(19) United States
(12) Patent Application Publication
(10) Pub. No.: US 2025/0271771 A1
(43) Pub. Date: Aug. 28, 2025

(54) VACUUM ULTRAVIOLET LIGHT MIRROR

(71) Applicant: KLA Corporation, Milpitas, CA (US)

(72) Inventors: John Savee, San Francisco, CA (US); Alexandro Vargas, Stockton, CA (US)

(21) Appl. No.: 19/059,039

(22) Filed: Feb. 20, 2025

Related U.S. Application Data
(60) Provisional application No. 63/556,417, filed on Feb. 22, 2024.

(51) Int. Cl. G03F 7/00; G02B 1/14; G02B 5/08

(52) U.S. Cl. CPC G03F 7/702; G02B 1/14; G02B 5/0891

(57) ABSTRACT

A mirror for reflecting vacuum ultraviolet light is disclosed. The VUV mirror may include a substrate. The VUV mirror may include a reflective layer deposited on the substrate, wherein the reflective layer is reflective of light of a wavelength between 100-200 nm. The VUV mirror may include a layer of noble metal deposited on the reflective layer, wherein the layer of noble metal provides environmental stability to the reflective layer and is transmissive to light of a wavelength between 100-200 nm.

### CROSS-REFERENCE TO RELATED APPLICATION

The present application claims priority to U.S. Provisional Application Ser. No. 63/556,417, filed Feb. 22, 2024, which is incorporated herein by reference in the entirety.

### TECHNICAL FIELD

The present disclosure relates to mirrors for use in vacuum ultraviolet (VUV) light optical systems and, in particular, reflective optical coatings for mirrors to maintain high reflectance in a wavelength range of 100-200 nm.

### BACKGROUND

Laser-sustained plasma (LSP) light sources are widely used in broadband inspection tools for generation of VUV light for use in semiconductor inspection and imaging. In the case of VUV plasma-based optical systems, few options exist for mirrors that maintain a moderately high reflectance between 100 and 200 nm in the vicinity of the bright plasma used for broadband light generation. Standard mirrors for high-intensity light are typically based on films of platinum or iridium, which have high stability but low reflectivity in this range. Coatings for low-intensity applications, such as magnesium fluoride protected aluminum, have high initial reflectivity but degrade rapidly when used near the bright plasma. Therefore, it is desirable to provide a mirror and method of forming the mirror that remedies the shortcomings of previous approaches as noted above.

### SUMMARY

A mirror for reflecting vacuum ultraviolet light is disclosed. In embodiments, the mirror includes a substrate. In embodiments, the mirror includes a reflective layer deposited on the substrate, wherein the reflective layer is reflective of light of a wavelength between 100-200 nm. In embodiments, the mirror includes a layer of noble metal deposited on the reflective layer, wherein the layer of noble metal provides environmental stability to the reflective layer and is transmissive to light of a wavelength between 100-200 nm. In embodiments, the mirror is implemented within a laser-sustained broadband light source. In embodiments, the mirror is implemented within an optical characterization system.

A method of forming a mirror for reflecting vacuum ultraviolet light is disclosed. In embodiments, the method includes providing a substrate. In embodiments, the method includes depositing a layer of aluminum on the substrate, wherein the layer of aluminum is reflective of light of a wavelength between 100-200 nm. In embodiments, the method includes depositing a layer of noble metal on the layer of aluminum, wherein the layer of noble metal provides environmental stability to the layer of aluminum and is transmissive to light of a wavelength between 100-200 nm.

It is to be understood that both the foregoing general description and the following detailed description are exemplary and explanatory only and are not necessarily restrictive of the present disclosure. The accompanying drawings, which are incorporated in and constitute a part of the specification, illustrate subject matter of the disclosure. Together, the descriptions and the drawings serve to explain the principles of the disclosure.

### BRIEF DESCRIPTION OF THE DRAWINGS

The numerous advantages of the disclosure may be better understood by those skilled in the art by reference to the accompanying figures.

FIG. 1 illustrates a series of penetration depth curves as a function of wavelength for various noble metals, in accordance with one or more embodiments of the present disclosure.

FIG. 2 illustrates a mirror displaying high reflectance to VUV light, in accordance with one or more embodiments of the present disclosure.

FIGS. 3A-3C illustrate a series of simulated reflectance data for VUV mirrors formed from platinum (Pt), iridium (Ir), and rhodium (Rh), in accordance with one or more embodiments of the present disclosure.

FIG. 4 illustrates a mirror with a capping layer displaying high reflectance to VUV light, in accordance with one or more alternative embodiments of the present disclosure.

FIGS. 5A-5C illustrate a series of simulated reflectance data for VUV mirrors formed from platinum (Pt), iridium (Ir), and rhodium (Rh) and equipped with a magnesium fluoride (MgF2) capping layer, in accordance with one or more embodiments of the present disclosure.

FIG. 6 illustrates a simplified schematic view of a laser-sustained plasma broadband light source implementing the VUV mirror, in accordance with one or more embodiments of the present disclosure.

FIG. 7 illustrates a simplified schematic view of an optical characterization system equipped with a laser-sustained plasma broadband light source implementing the VUV mirror, in accordance with one or more embodiments of the present disclosure.

FIG. 8 illustrates a process flow diagram depicting a method of forming a VUV mirror, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

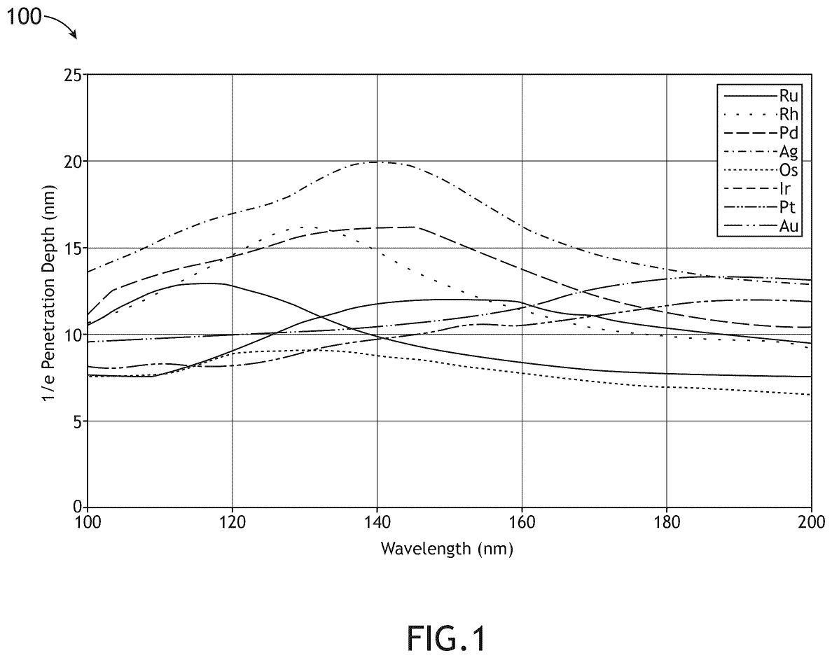

Referring generally to FIGS. 1-7, a VUV mirror suitable for operation in the vicinity of a VUV laser-sustained plasma broadband light source is described, in accordance with one or more embodiments of the present disclosure.

Embodiments of the present disclosure are directed to reflective optical coatings for use in mirrors in broadband plasma optical systems. The reflective coatings of the present disclosure may include one or more reflective layers (e.g., aluminum film) protected by a thin protective layer of noble metal. The coatings exploit the high reflectivity of aluminum to VUV light (e.g., 100-200 nm) and the environmental stability of noble metals in harsh environments resulting in reflective optics that do not degrade after long periods of use in laser sustained plasma-based light sources. Several practical optical designs are described to exploit the basic noble metal-aluminum film stack.

Embodiments of the present disclosure take advantage of the chemical inertness of the noble metals (e.g., Ru, Rh, Pd, Ag, Os, Ir, Pt, and Au) and their moderate transmission for photons in the 100-200 nm range. As shown in FIG. 1, the 1/e transmission depth for most noble metals (i.e., the depth at which the noble metal has absorbed approximately 63% of the incident photons) is on the order of 10-20 nm for photons with wavelengths in the 100-200 nm range. This depth indicates that very thin (few nm thick) layers of noble metals may be used to provide environmentally stable protective layers above more reflective materials (e.g., aluminum) that would otherwise be destroyed in the harsh environment near a plasma. By way of example, aluminum provides a markedly higher reflectance in the 100-200 nm range than any other known material. However, aluminum rapidly reacts with oxygen or fluorine containing species to form surface oxides or fluorides. These oxides or fluorides will change the optical properties of the initial aluminum layer and may significantly reduce reflectance in the 100-200 nm band. Thus, the use of aluminum as a reflective material in the 100-200 nm range requires a transparent (or semi-transparent) protective layer to prevent chemical change to the initial aluminum layer.

Embodiments of the present disclosure utilize thin noble metal films to provide a transmissive, but environmentally stable, protection layer above a highly reflective reflection layer (e.g., aluminum layer). The overall reflectivity of the film stack can be tuned (i.e., by reducing the thickness of the noble metal layer) at the expense of the environmental protection provided by the noble metal film. This allows optimization of reflective optics for a specific application.

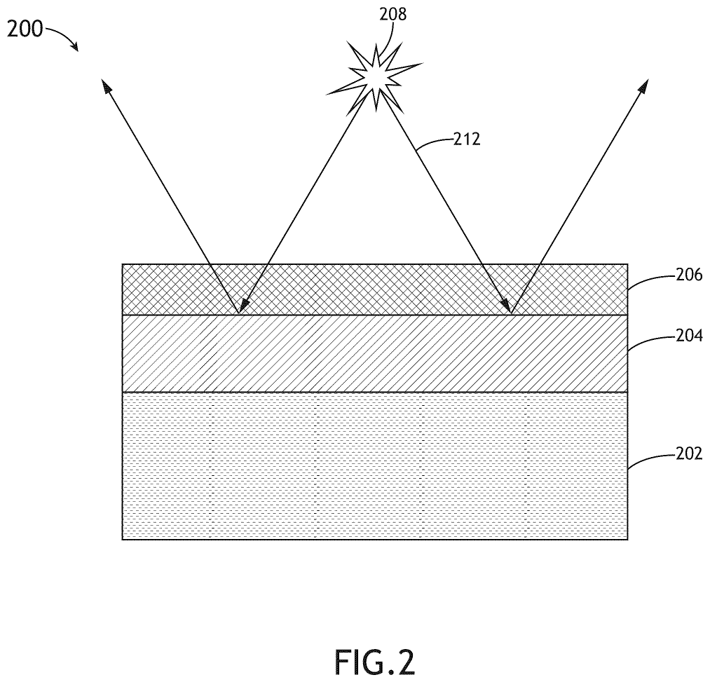

FIG. 2 illustrates a mirror 200 for implementation within a LSP broadband light source, in accordance with one or more embodiments of the present disclosure.

In embodiments, the mirror 200 includes a substrate 202, a reflective layer 204, and a layer of noble metal 206. In embodiments, the reflective layer is reflective of light of VUV light (e.g., wavelength between 100-200 nm). For example, the reflective layer 204 may include, but is not limited to, a layer of aluminum. In this example, the layer of noble metal 206 may be deposited on the layer of aluminum. The layer of noble metal 206 provides environmental stability to the layer of reflective layer 204 and is transmissive of VUV light (e.g., wavelength between 100-200 nm). For example, the mirror 200 may be used to collect and reflect broadband light 212 emitted by a laser-sustained plasma 208. In this example, the noble metal 206 may transmit broadband light 212 emitted by the plasma 208. The broadband light 212 transmitted through the layer of noble metal 206 is then reflected by the reflective layer 204 and transmitted back through the layer of noble metal 206 and utilized at a location downstream from the mirror 200.

The substrate 202 may include any suitable material that will permit deposition of the aluminum and noble metal coatings. For example, the substrate 202 may include, but is not limited to, fused silica, MgF₂, CaF₂, or silicon. In embodiments, the substrate 202 may be flat to form a flat mirror surface. In alternative embodiments, the substrate 202 may include a more complex optical surface (e.g., spherical, parabolic, elliptical) to form a curved mirror surface. The deposited aluminum layer should be as dense and chemically pure as possible (e.g., free of oxygen) and thick enough to be optically opaque in the 100-200 nm wavelength range (e.g., greater than 100 nm) to prevent photons from reaching the aluminum-substrate interface. Likewise, the noble metal film should be dense and free of impurities.

The noble metal used to form the layer of noble metal 206 may include any noble metal. For example, the noble metal may include Ru, Rh, Pd, Ag. Os, Ir, Pt, or Au. In embodiments, thickness of the layer of noble metal 206 is selected such that the layer of noble metal 206 is transmissive of the broadband light 212. For example, the layer of noble metal 206 may be deposited such that the layer is between 2 and 8 nm in thickness.

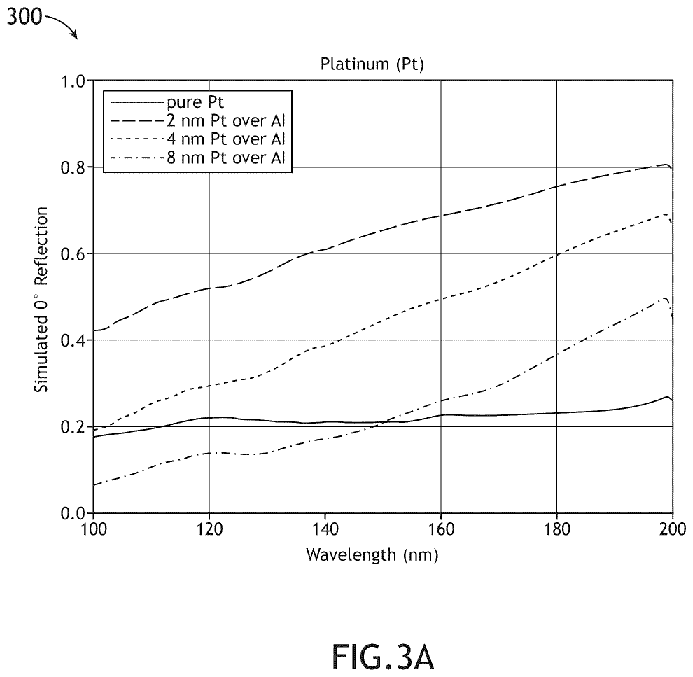

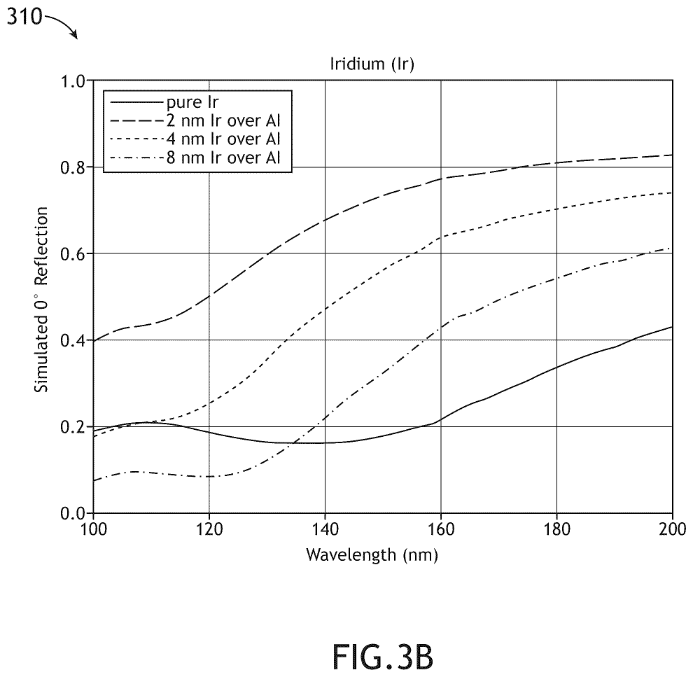

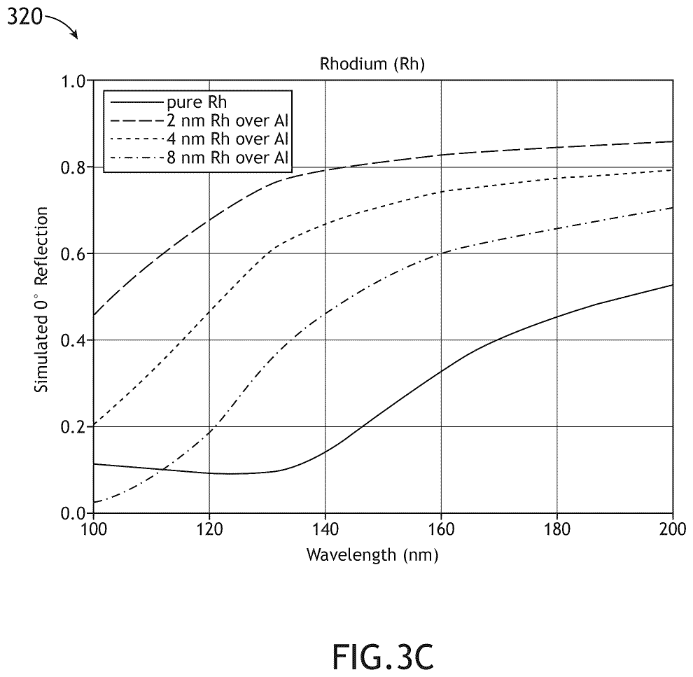

FIGS. 3A-3C illustrate a series of simulated reflectance data for mirrors formed from Pt, Ir, and Rh. FIG. 3A illustrates a graph 300 depicting a series of simulated reflectance curves as a function of wavelength for aluminum mirrors coated with 2 nm of Pt, 4 nm of Pt, and 8 nm of Pt. A reflectance curve for pure Pt to provide baseline reflectance information is also provided. FIG. 3B illustrates a graph 310 depicting a series of simulated reflectance curves as a function of wavelength for aluminum mirrors coated with 2 nm of Ir, 4 nm of Ir, and 8 nm of Ir. A reflectance curve for pure Ir to provide baseline reflectance information is also provided. FIG. 3C illustrates a graph 320 depicting a series of simulated reflectance curves as a function of wavelength for aluminum mirrors coated with 2 nm of Rh, 4 nm of Rh, and 8 nm of Rh. A reflectance curve for pure Rh to provide baseline reflectance information is also provided. The behavior demonstrated in FIGS. 3A-3C illustrates that by the time the noble metal layer thickness reaches 8 nm, absorbance of the noble metal layer becomes too large to take advantage of the reflectivity of the aluminum sublayer. However, intermediate noble metal layer thicknesses can be tuned to trade environmental stability (e.g., thicker noble metal layers) for reflectance (e.g., thinner noble metal layers) to meet the requirements for a particular application.

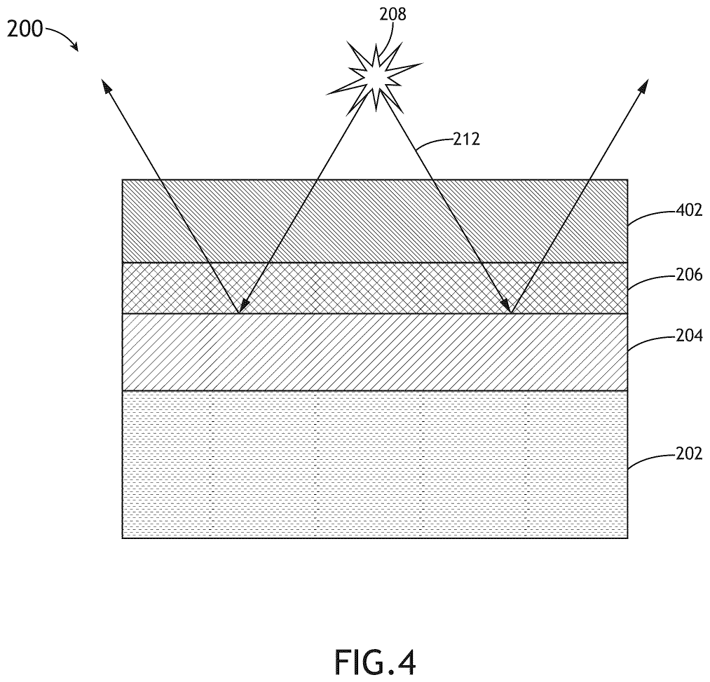

FIG. 4 illustrates mirror 200 including an additional capping layer 402 for implementation within a LSP broadband light source, in accordance with one or more alternative and/or additional embodiments of the present disclosure.

In embodiments, the capping layer 402 includes an oxide or a fluoride. For example, the capping layer 402 may include a metal oxide or silicon dioxide. For instance, in the case of a metal oxide, the metal oxide may include, but is not limited to, aluminum oxide. By way of another example, the capping layer 402 may include a metal fluoride. For instance, the metal fluoride may include, but is not limited to, lithium fluoride, magnesium fluoride, or calcium fluoride. It is noted that the capping layer 402 may be transparent over large portions of the 100-200 nm wavelength band.

In embodiments, the layer of noble metal 206 may act as a diffusion barrier between the capping layer 402 and the reflective layer 204. For low lifetime dose applications, metal oxide or metal fluoride coatings may be placed directly above a reflective aluminum layer at a thickness that prevents oxygen or fluorine containing species in the surrounding atmosphere from interacting with the reflective layer 204 (e.g., layer of aluminum). The thickness of this metal oxide or metal fluoride capping layer can also be chosen to exploit constructive interference in a small band around a given wavelength. Without a protection layer, metal oxide or metal fluoride coatings will degrade rapidly in the vicinity of a bright plasma due to photochemistry that ultimately leads to the diffusion of oxygen or fluorine into the reflective aluminum layer. If a thin noble metal layer is placed between the aluminum layer and the metal oxide or metal fluoride capping layer 402, the layer of noble metal 206 will behave as a diffusion barrier preventing degradation of optical performance that is caused by migration of oxygen or fluorine into the aluminum layer 402.

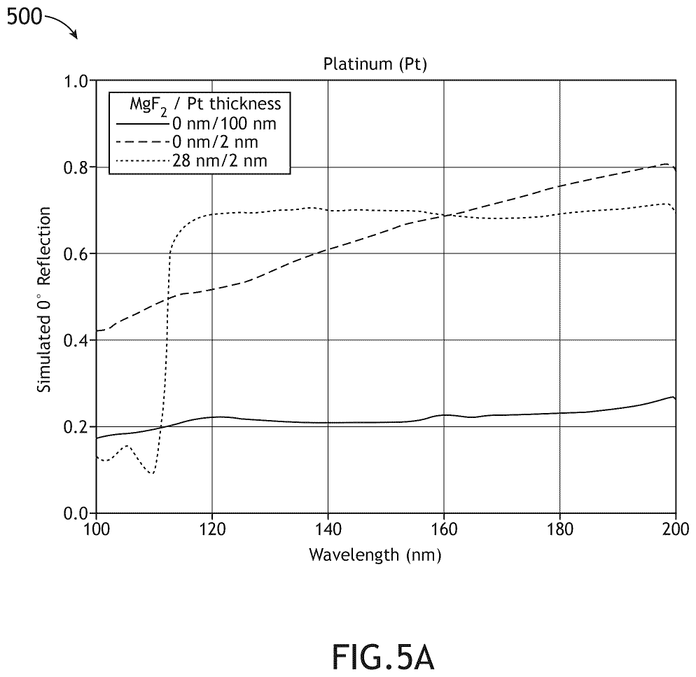

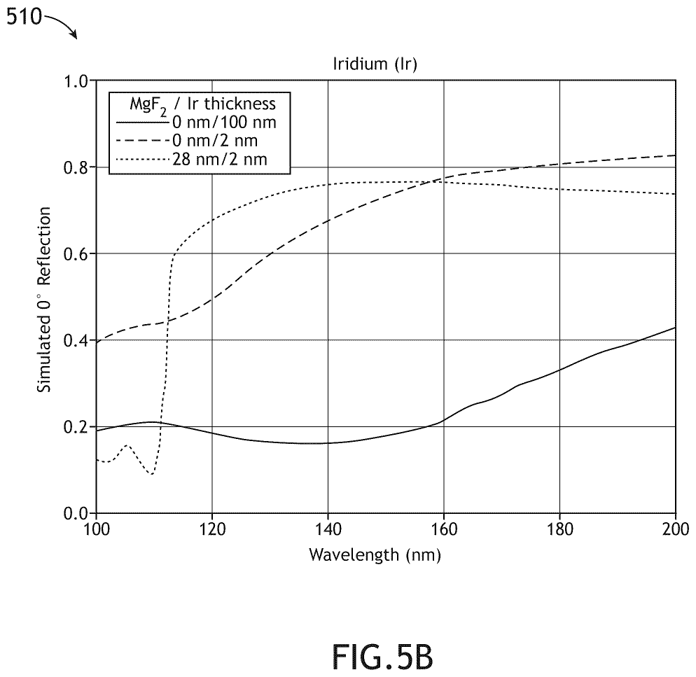

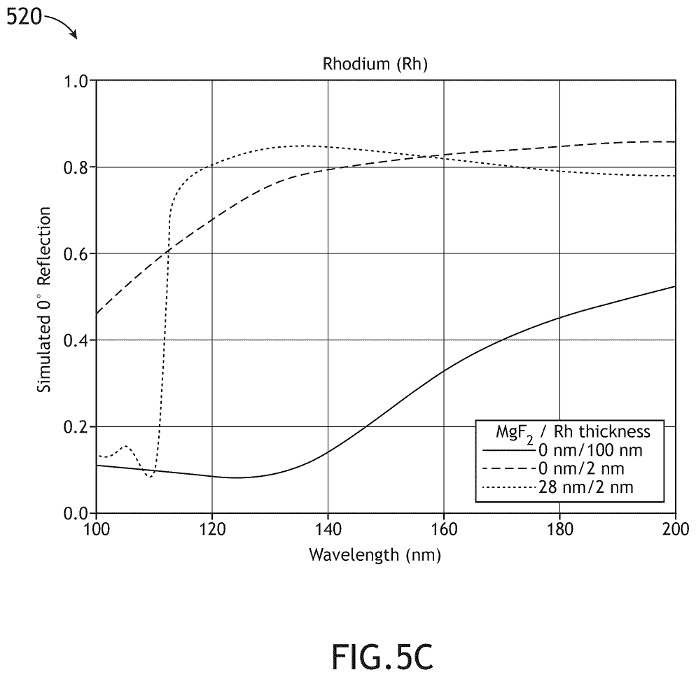

FIGS. 5A-5C illustrate a series of simulated reflectance data for mirrors formed from Pt, Ir, and Rh with a magnesium fluoride capping layer 402, in accordance with one or more embodiments of the present disclosure. FIG. 5A illustrates a graph 500 depicting a series of simulated reflectance curves as a function of wavelength including a bare Pt mirror (e.g., 100 nm thick Pt), an aluminum coated mirror protected with 2 nm Pt protective layer, and an aluminum coated mirror protected with 2 nm Pt protective layer and a 28 nm MgF₂ capping layer. FIG. 5B illustrates a graph 510 depicting a series of simulated reflectance curves as a function of wavelength including a bare Ir mirror (e.g., 100 nm thick Ir), an aluminum coated mirror protected with 2 nm Ir protective layer, and an aluminum coated mirror protected with 2 nm Ir protective layer and a 28 nm MgF₂capping layer. FIG. 5C illustrates a graph 520 depicting a series of simulated reflectance curves as a function of wavelength including a bare Rh mirror (e.g., 100 nm thick Rh), an aluminum coated mirror protected with 2 nm Rh protective layer, and an aluminum coated mirror protected with 2 nm Rh protective layer and a 28 nm MgF₂ capping layer. It is noted that the MgF₂ capping layer is optimized for maximum reflectance near 120 nm. If the metal oxide or metal fluoride coating can be maintained during use near a bright plasma, the optical design presented in FIG. 4 may be used to further enhance reflectivity over small sub-bands in the wavelength range 100-200 nm (e.g., near 120 nm in this example).

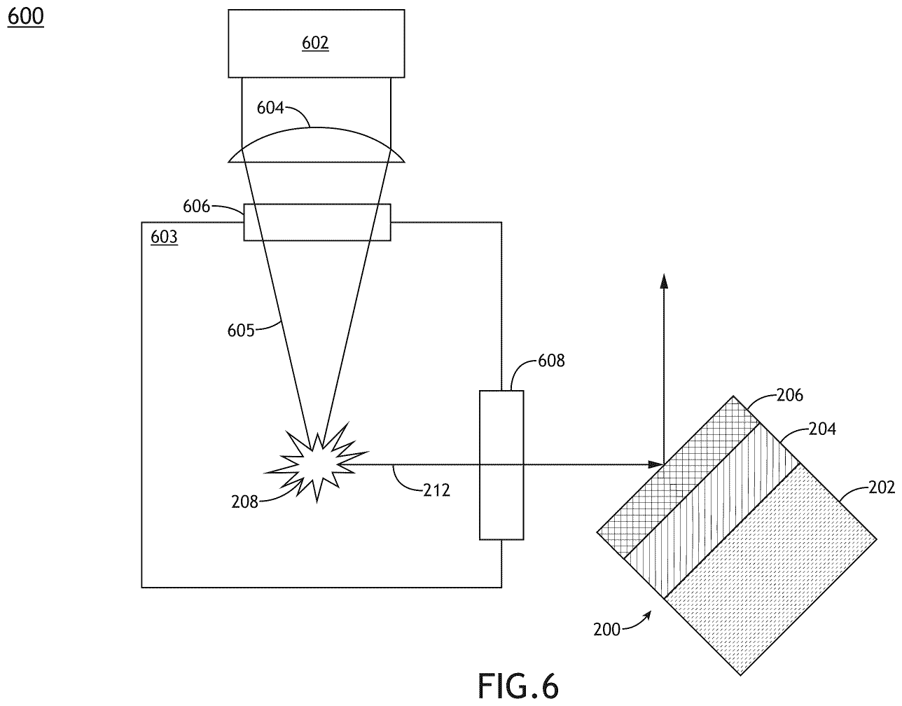

FIG. 6 illustrates a simplified schematic view of a LSP broadband light source 600 incorporating the VUV mirror 200, in accordance with one or more embodiments. In embodiments, the light source 600 includes a gas containment structure 603 for containing a selected gas or gas mixture (e.g., xenon, argon, krypton, and mixtures thereof). In embodiments, the light source 600 includes a laser pump source 602 configured to generate an optical pump 605. The laser pump source 602 and one or more focusing optics 604 may direct and focus the optical pump 605 through an input optical window 606 to sustain the plasma 208 within the gas containment structure 603 to generate broadband light 212. The laser pump source 602 may include any laser known in the art of plasma-based broadband light generation such as, but not limited to, one or more continuous wave (CW) pump lasers and/or one or more pulsed lasers. The laser pump source 602 may be configured to emit light in the visible, IR (e.g., NIR), or ultraviolet regions. In embodiments, broadband light 212 exits the gas containment structure 603 through exit window 608. In embodiments, the VUV mirror 200 receives and reflects the broadband light 212 to one or more downstream applications. It is noted that the configuration depicted in FIG. 6 should not be interpreted as a limitation on the scope of the present disclosure. It is recognized herein that the mirror 200 may be implemented in any broadband light generation context which may entail different gas containment arrangements (e.g., plasma bulb, plasma cell, plasma chamber), different light collection arrangements (e.g., flat mirrors, curved reflectors) and the location of the mirror 200 relative to the plasma 208. For example, the mirror 200 may be placed in vicinity to the plasma within the gas containment structure 603.

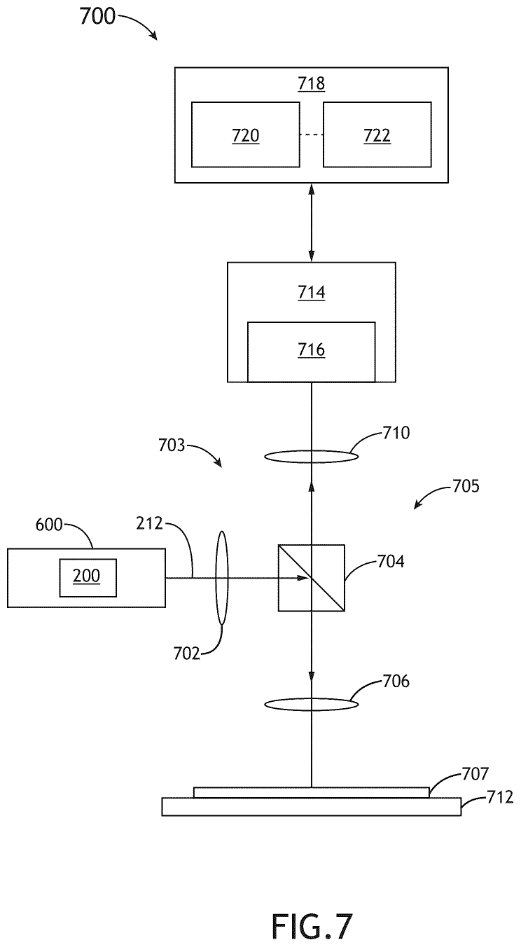

FIG. 7 illustrates a simplified schematic view of an optical characterization system 700 incorporating the LSP broadband light source 600 incorporating the one or more mirrors 200, in accordance with one or more embodiments of the present disclosure. In embodiments, system 700 includes the LSP light source 600 including one or more mirrors 200, an illumination arm 703, a collection arm 705, a detector assembly 714, and a controller 718 including one or more processors 720 and memory 722.

It is noted herein that system 700 may comprise any imaging, inspection, metrology, lithography, or other characterization system known in the art. In this regard, system 700 may be configured to perform inspection, optical metrology, lithography, and/or any form of imaging on a sample 707. Sample 707 may include any sample known in the art including, but not limited to, a wafer, a reticle, a photomask, and the like. It is noted that system 700 may incorporate one or more of the various embodiments of the LSP light source 600 and one or more mirrors 200 described throughout the present disclosure.

In one embodiment, sample 707 is disposed on a stage assembly 712 to facilitate movement of sample 707. Stage assembly 712 may include any stage assembly 712 known in the art including, but not limited to, an X-Y stage, an R-θ stage, and the like.

In one embodiment, the illumination arm 703 is configured to direct broadband light 212 from the Broadband LSP light source 600 to the sample 707. The illumination arm 703 may include any number and type of optical components known in the art. In one embodiment, the illumination arm 703 includes one or more optical elements 702, a beam splitter 704, and an objective lens 706. In this regard, illumination arm 703 may be configured to focus broadband light 212 from the broadband LSP light source 600 onto the surface of the sample 707. The one or more optical elements 702 may include any optical element or combination of optical elements known in the art including, but not limited to, one or more mirrors, one or more lenses, one or more polarizers, one or more gratings, one or more filters, one or more beam splitters, and the like. It is noted herein that the collection location may include, but is not limited to, one or more of the optical elements 702, a beam splitter 704, or an objective lens 706.

In one embodiment, system 700 includes a collection arm 705 configured to collect light reflected, scattered, diffracted, and/or emitted from sample 707. In another embodiment, collection arm 705 may direct and/or focus the light from the sample 707 to a sensor 716 of a detector assembly 714. It is noted that sensor 716 and detector assembly 714 may include any sensor and detector assembly known in the art.

In one embodiment, detector assembly 714 is communicatively coupled to a controller 718 including one or more processors 720 and memory 722. For example, the one or more processors 720 may be communicatively coupled to memory 722, wherein the one or more processors 720 are configured to execute a set of program instructions stored on memory 722. In one embodiment, the one or more processors 720 are configured to analyze the output of detector assembly 714.

It is noted that the system 700 may be configured in any optical configuration known in the art including, but not limited to, a dark-field configuration, a bright-field orientation, and the like. The system 700 may be configured as any type of inspection tool or metrology tool known in the art.

Additional details of various embodiments of optical characterization system 700 are described in U.S. Published U.S. Pat. No. 7,957,066B2, entitled “Split Field Inspection System Using Small Catadioptric Objectives,” issued on Jun. 7, 2011; U.S. Published Patent Application 2007/0002465, entitled “Beam Delivery System for Laser Dark-Field Illumination in a Catadioptric Optical System,” published on Jan. 4, 2007; U.S. Pat. No. 5,999,310, entitled “Ultra-broadband UV Microscope Imaging System with Wide Range Zoom Capability,” issued on Dec. 7, 1999; U.S. Pat. No. 7,525,649 entitled “Surface Inspection System Using Laser Line Illumination with Two Dimensional Imaging,” issued on Apr. 28, 2009; U.S. Published Patent Application 2013/0114085, entitled “Dynamically Adjustable Semiconductor Metrology System,” by Wang et al. and published on May 9, 2013; U.S. Pat. No. 5,608,526, entitled “Focused Beam Spectroscopic Ellipsometry Method and System, by Piwonka-Corle et al., issued on Mar. 4, 1997; and U.S. Pat. No. 6,297,880, entitled “Apparatus for Analyzing Multi-Layer Thin Film Stacks on Semiconductors,” by Rosencwaig et al., issued on Oct. 2, 2001, which are each incorporated herein by reference in their entirety.

The one or more processors 720 of the present disclosure may include any one or more processing elements known in the art. In this sense, the one or more processors 720 may include any microprocessor-type device configured to execute software algorithms and/or instructions. In one embodiment, the one or more processors 720 may consist of a desktop computer, mainframe computer system, workstation, image computer, parallel processor, or other computer system (e.g., networked computer) configured to execute a program configured to operate the system 700 and/or broadband LSP light source 600, as described throughout the present disclosure. It should be recognized that the steps described throughout the present disclosure may be carried out by a single computer system or, alternatively, multiple computer systems. In general, the term “processor” may be broadly defined to encompass any device having one or more processing elements, which execute program instructions from the memory 722 (e.g., non-transitory memory medium). Moreover, different subsystems of the various systems disclosed may include processor or logic elements suitable for carrying out at least a portion of the steps described throughout the present disclosure. Therefore, the above description should not be interpreted as a limitation on the present disclosure but merely an illustration.

The memory 722 may include any storage medium known in the art suitable for storing program instructions executable by the associated one or more processors 720. For example, the memory 722 may include a non-transitory memory medium. For instance, the memory 722 may include, but is not limited to, a read-only memory, a random-access memory, a magnetic or optical memory device (e.g., disk), a magnetic tape, a solid state drive, and the like. In another embodiment, the memory 722 is configured to store one or more results and/or outputs of the various steps described herein. It is further noted that memory 722 may be housed in a common controller housing with the one or more processors 720. In an alternative embodiment, the memory 722 may be located remotely with respect to the physical location of the processors 720. For instance, the one or more processors 720 may access a remote memory (e.g., server), accessible through a network (e.g., internet, intranet, and the like). In another embodiment, memory 722 maintains program instructions for causing the one or more processors 720 to carry out the various steps described through the present disclosure.

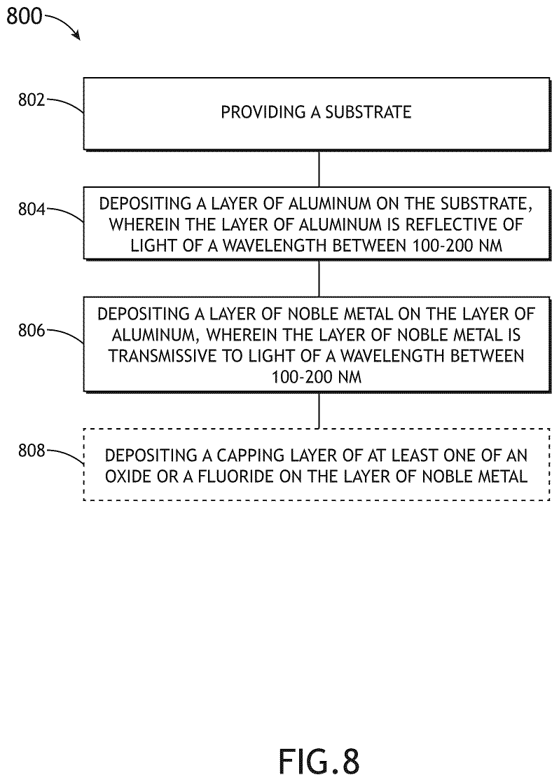

FIG. 8 illustrates a process flow diagram depicting a method 800 of forming a VUV mirror for reflection of vacuum ultraviolet light, in accordance with one or more alternative and/or additional embodiments. It is noted herein that the steps of method 800 may incorporate all or part of the features of the mirror 200. It is further recognized, however, that the method 800 is not limited to the mirror 200.

In step 802, the method 800 includes providing a substrate. In step 804, the method 800 includes depositing a layer of aluminum on the substrate. In embodiments, the layer of aluminum is reflective of light of a wavelength between 100-200 nm. The aluminum layer may be deposited in any manner known in the art of thin film deposition. For example, the aluminum layer may be deposited via chemical vapor deposition, sputtering, or evaporation.

In step 806, the method 800 includes depositing a layer of noble metal on the layer of aluminum. In embodiments, the layer of noble metal provides environmental stability to the layer of aluminum and is transmissive to light of a wavelength between 100-200 nm. The noble metal layer may be deposited in any manner known in the art of thin film deposition. For example, the noble metal layer may be deposited via chemical vapor deposition, sputtering, or evaporation.

In step 808, the method 800 includes an additional step of depositing a capping layer of at least one of an oxide or a fluoride on the layer of noble metal. In embodiments, the capping layer may include an oxide or fluoride material (e.g., metal oxide or metal fluoride). The capping layer may be deposited in any manner known in the art of thin film deposition. For example, the capping layer may be deposited via chemical vapor deposition, sputtering, or evaporation.

One skilled in the art will recognize that the herein described components, operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, devices, and objects should not be taken as limiting.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

1. A mirror comprising:
a substrate;
a reflective layer deposited on the substrate, wherein the reflective layer is reflective of light of a wavelength between 100-200 nm; and
a layer of noble metal deposited on the reflective layer, wherein the layer of noble metal provides environmental stability to the reflective layer and is transmissive to light of a wavelength between 100-200 nm.

2. The mirror of claim 1, wherein the noble metal comprises at least one of Ru, Rh, Pd, Ag, Os, Ir, Pt, or Au.

3. The mirror of claim 1, wherein the layer of noble metal is between 2 and 8 nm in thickness.

4. The mirror of claim 1, wherein the reflective layer comprises a layer of aluminum.

5. The mirror of claim 4, wherein the layer of aluminum is greater than 100 nm in thickness.

6. The mirror of claim 1, further comprising: a capping layer, wherein the capping layer comprises at least one of an oxide or a fluoride deposited on the layer of noble metal.

7. The mirror of claim 6, wherein the layer of noble metal acts as a diffusion barrier between the reflective layer and the capping layer.

8. The mirror of claim 6, wherein the oxide comprises at least one of a metal oxide or silicon dioxide.

9. The mirror of claim 8, wherein the metal oxide comprises aluminum oxide.

10. The mirror of claim 6, wherein the fluoride comprises a metal fluoride comprising at least one of lithium fluoride, magnesium fluoride, or calcium fluoride.

11. The mirror of claim 1, wherein the substrate comprises at least one of a flat substrate or a curved substrate.

12. A laser-sustained broadband light source comprising:
a gas containment structure for containing a gas;
a laser pump source configured to generate an optical pump to sustain a plasma within the gas containment structure; and
a mirror configured to reflect broadband light generated by the plasma, wherein the mirror comprises:
a substrate;
a reflective layer deposited on the substrate, wherein the reflective layer is reflective of light of a wavelength between 100-200 nm; and
a layer of noble metal deposited on the reflective layer, wherein the layer of noble metal provides environmental stability to the reflective layer and is transmissive to light of a wavelength between 100-200 nm.

13. The source of claim 12, wherein the noble metal comprises at least one of Ru, Rh, Pd, Ag, Os, Ir, Pt, or Au.

14. The source of claim 12, wherein the layer of noble metal is between 2 and 8 nm in thickness.

15. The source of claim 12, wherein the reflective layer comprises a layer of aluminum.

16. The source of claim 12, wherein the layer of aluminum is greater than 100 nm in thickness.

17. The source of claim 12, further comprising: a capping layer, wherein the capping layer comprises at least one of an oxide or a fluoride deposited on the layer of noble metal.

18. The source of claim 17, wherein the layer of noble metal acts as a diffusion barrier between the reflective layer and the capping layer.

19. The source of claim 18, wherein the oxide comprises at least one of a metal oxide or silicon dioxide.

20. The source of claim 19, wherein the metal oxide comprises aluminum oxide.

21. The source of claim 17, wherein the fluoride comprises a metal fluoride comprising at least one of lithium fluoride, magnesium fluoride, or calcium fluoride.

22. The source of claim 12, wherein the substrate comprises at least one of a flat substrate or a curved substrate.

23. A characterization system comprising:
a broadband light source comprising:
a gas containment structure for containing a gas;
a laser pump source configured to generate an optical pump to sustain a plasma within the gas containment structure;
a mirror configured to reflect broadband light generated by the plasma toward one or more downstream optical elements, wherein the mirror comprises:
a substrate;
a reflective layer deposited on the substrate, wherein the reflective layer is reflective of light of a wavelength between 100-200 nm; and
a layer of noble metal deposited on the reflective layer, wherein the layer of noble metal provides environmental stability to the reflective layer and is transmissive to light of a wavelength between 100-200 nm;
a set of illumination optics configured to direct broadband light from the broadband light source to one or more samples;
a set of collection optics configured to collect light from the one or more samples; and
a detector assembly.

24. The system of claim 23, wherein the characterization system comprises at least one of an inspection system or a metrology system.

25. The system of claim 23, further comprising: a capping layer, wherein the capping layer comprises at least one of an oxide or a fluoride deposited on the layer of noble metal.

26. A method of forming a mirror for reflection of vacuum ultraviolet light comprising:
providing a substrate;
depositing a layer of aluminum on the substrate, wherein the layer of aluminum is reflective of light of a wavelength between 100-200 nm; and
depositing a layer of noble metal on the layer of aluminum, wherein the layer of noble metal provides environmental stability to the layer of aluminum and is transmissive to light of a wavelength between 100-200 nm.

27. The method of claim 26, further comprising:
depositing a capping layer of at least one of an oxide or a fluoride on the layer of noble metal.
